(19) United States
(12) Patent Application Publication
(10) Pub. No.: US 2025/0112064 A1
(43) Pub. Date: Apr. 3, 2025

(54) CHAMBER ARRANGEMENTS, SEMICONDUCTOR PROCESSING SYSTEMS INCLUDING CHAMBER ARRANGEMENTS AND RELATED MATERIAL LAYER DEPOSITION METHODS

(71) Applicant: ASM IP Holding B.V., Almere (NL)

(72) Inventors: Amir Kajbafvala, Chandler, AZ (US); Arun Murali, Tempe, AZ (US); Caleb Miskin, Mesa, AZ (US); Frederick Aryeetey, Phoenix, AZ (US); Alexandros Demos, Scottsdale, AZ (US)

(21) Appl. No.: 18/900,352

(22) Filed: Sep. 27, 2024

Related U.S. Application Data
(60) Provisional application No. 63/586,771, filed on Sep. 29, 2023.

(51) Int. Cl. H01L 21/67

(52) U.S. Cl. CPC H01L 21/67248; H01L 21/67115

(57) ABSTRACT

A chamber arrangement for a semiconductor processing system includes a chamber body, a substrate support, a first chamber pyrometer, and a second chamber pyrometer. The chamber body has an exterior surface, a hollow interior, and the substrate support is supported for rotation within the interior of the chamber body. The first chamber pyrometer and second chamber pyrometer are optically coupled to the exterior surface of the chamber body. The first chamber pyrometer is configured to acquire a first temperature measurement at a first location on the exterior surface of the chamber body, and the second chamber pyrometer is configured to acquire a second temperature measurement at a second location on the exterior surface of the chamber body. The second location is offset from the first location to throttle temperature across the exterior surface of the chamber body between the first location and the second location. Material layer deposition methods and computer program products are also described.

### CROSS-REFERENCE TO RELATED APPLICATION(S)

This application claims the benefit of U.S. Provisional Application 63/586,771 filed on Sep. 29, 2023, the entire contents of which are incorporated herein by reference.

### FIELD OF INVENTION

The present disclosure generally relates to fabricating semiconductor devices, and more particularly to depositing material layers onto substrates during the fabrication of semiconductor devices.

### BACKGROUND OF THE DISCLOSURE

Material layers are commonly deposited onto substrates during the fabrication of semiconductor devices, such as integrated circuits and power electronics. Material layer deposition is generally accomplished by seating the substrate within a reactor on a substrate support, heating the substrate to a desired material layer deposition temperature, and exposing the substrate to one or more material layer precursors such that a material layer forms on the substrate under environmental conditions selected to cause a material layer to deposit onto the substrate. Once the material layer reaches a desired thickness, the flow of material layer precursors ceases and the substrate is unseated from the substrate support so that the substrate may be sent on for further processing, as appropriate for the material layer being deposited onto the substrate. Heating the substrate, and consequentially the chamber body which houses the substrate and substrate support, may be accomplished through the use of heating elements surrounding the chamber body and blowers.

Prior to and during the formation of material layers, the thermal properties of the semiconductor system must be considered. For example, if the temperature of the substrate is too low for a selected material deposition the material may not adhere to the substrate or may be deposited in a non-uniform manner. An event like this may result in a scrapped substrate and loss of productivity. Conversely, a single temperature is not suitable for all material types to be deposited onto the substrate. In the instance where a specific temperature is suitable for a particular material, that same temperature may cause another material to decompose or be deposited at an undesirable rate. Therefore, access to a wide range of temperatures is necessary for the multitude of material types. Knowing and controlling the temperature of the substrate and chamber body are necessary.

Various techniques are deployed to measure and control the temperature of the substrate and/or the chamber body of the semiconductor system. For example, thermocouples may be placed around the substrate and chamber body or in another component of the chamber body to measure the temperature. Another technique is through optical means. A pyrometer uses the intensity of the emitted radiation from an object to determine the temperature of the object. Control of the temperature properties may be performed by altering the applied heat to the semiconductor system in response to the measured results.

Such methods and systems have generally been considered suitable for their intended purpose. However, there remains a need in the art for improved chamber arrangements, semiconductor processing systems having chamber arrangements, and related material layer deposition methods. The present disclosure provides a solution to this need.

### SUMMARY OF THE DISCLOSURE

A chamber arrangement for a semiconductor processing system is provided. The chamber arrangement includes a chamber body, a substrate support, a first chamber pyrometer, and a second chamber pyrometer. The chamber body has an exterior surface and a hollow interior. The substrate support is arranged with the interior of the chamber body and is supported within the interior of the chamber body for rotation about a rotation axis. The first chamber pyrometer is optically coupled to the exterior surface of the chamber body at a first location and is configured to acquire a first temperature measurement indicative of temperature of the exterior surface of the chamber body at the first location. The second chamber pyrometer is optically coupled to the exterior surface of the chamber body at a second location and is configured to acquire a second temperature measurement indicative of temperature of the exterior surface of the chamber body at the second location. The second location is offset from the first location to throttle heat communicated into the interior of the chamber body according to a wall temperature difference between the first location and the second location on the exterior surface of the chamber body calculated using the first temperature measurement and the second temperature measurement.

In addition to one or more of the features described above, or as an alternative, further examples may include that the chamber body is formed from a transparent material. The substrate support may be formed from an opaque material.

In addition to one or more of the features described above, or as an alternative, further examples may include that the chamber body has an injection end and a longitudinally opposite exhaust end. The second location on the exterior surface of the chamber body may be longitudinally offset from the first location on the exterior surface of the chamber between the injection end and the exhaust end of the chamber body.

In addition to one or more of the features described above, or as an alternative, further examples may include that the chamber body has first sidewall and a laterally opposite second sidewall. The second location on the exterior surface of the chamber body may be laterally offset from the first location on the exterior surface of the chamber body between the first sidewall and the second sidewall.

In addition to one or more of the features described above, or as an alternative, further examples may include a substrate pyrometer. The substrate pyrometer may be optically coupled to the interior of the chamber body by an optical axis intersecting the substrate support.

In addition to one or more of the features described above, or as an alternative, further examples may include a third chamber pyrometer. The third chamber pyrometer may be supported below the chamber body and configured to acquire the temperature at a third location on an exterior surface of a lower wall of the chamber body.

In addition to one or more of the features described above, or as an alternative, further examples may include that at least one of the first location and the second location on the exterior surface of the chamber body overlays the substrate support arranged within the chamber body.

In addition to one or more of the features described above, or as an alternative, further examples may include that the substrate support separates the second location from the first location.

A semiconductor processing system is provided. The semiconductor processing system includes a chamber arrangement as described above, an upper heater element array, and a controller. The upper heater element array is supported above the chamber body and is optically coupled to the interior of the chamber body by an upper wall of the chamber body. The controller is operatively connected to the upper heater element array and is disposed in communication with both the first chamber pyrometer and the second chamber pyrometer. The controller is further responsive to instructions recorded on a memory to receive the first temperature measurement from the first chamber pyrometer, receive the second temperature measurement from the second chamber pyrometer, determine a longitudinal wall temperature difference using the first temperature measurement and the second temperature measurement, and throttle the heating of the chamber body when the longitudinal wall temperature difference is greater than a predetermined wall temperature difference value using the upper heater element array.

In addition to one or more of the features described above, or as an alternative, further examples may include that the upper heater element array includes a first upper heater element and a second upper heater element. The first upper heater element may extend laterally above the chamber body, the second upper heater element may extend in parallel with the first upper heater element, and, heating of the chamber body may be throttled by increasing the power applied to one of the first upper heater element and the second upper heater element relative to the other first upper heater element and the second upper heater element.

In addition to one or more of the features described above, or as an alternative, further examples may include a lower heater element array. The lower heater element array may be supported below the chamber body, optically coupled to the substrate support by a lower wall of the chamber body, and operably associated with the controller. The instructions recorded on the memory may further cause the controller to throttle the heating of the substrate support by the lower heater element array when the wall temperature difference determined using the first temperature measurement and the second temperature measurement difference is greater than the predetermined wall temperature difference value.

In addition to one or more of the features described above, or as an alternative, further examples may include that the instructions further cause the controller to determine a lateral temperature offset using the longitudinal wall temperature difference. Heating of the substrate support by a lower heater element array may be throttled using the lateral temperature offset.

In addition to one or more of the features described above, or as an alternative, further examples may include that the lower heater element array comprises a first lower heater element and a second lower heater element. The first lower heater element may extend longitudinally below the chamber body, the second lower heater element may extend in parallel with the first lower heater element, and throttling of the lower heater element array using the lateral temperature offset may include changing power applied to one of the first lower heater element and the second lower heater element relative to the other of the first lower heater element and the second lower heater element.

In addition to one or more of the features described above, or as an alternative, further examples may include that the lower heater element array comprises a first lower spot lamp and a second lower spot lamp. The first lower spot lamp may underly the substrate support, the second lower spot lamp may also underly the substrate support and additionally be offset from the first lower spot lamp about the rotation axis, and throttling the lower heater element array using a lateral temperature offset may further include increasing the power applied to one of the first lower spot lamp and the second lower spot lamp relative to the other of the first lower spot lamp and the second lower spot lamp.

In addition to one or more of the features described above, or as an alternative, further examples may include a first blower and a second blower. The first blower may be supported below the chamber body and in pneumatic communication with the exterior surface of the chamber body. The second blower may also be supported below the chamber body and in pneumatic communication with the exterior surface the chamber body and may additionally be laterally spaced apart from the first blower below the lower wall of the chamber body. The controller may be operably connected to the first blower and the second blower, and the instructions recorded on the memory may further cause the controller to throttle mass flow rate of coolant through one of the first blower and the second blower relative to mass flow rate of coolant through the other of the first blower and the second blower when the wall temperature difference determined using the first temperature measurement and the second temperature measurement is greater than the predetermined wall temperature difference value.

In addition to one or more of the features described above, or as an alternative, further examples may include a chamber arrangement as described above, a first blower, a second blower, and a controller. The first blower is supported below the chamber body and in pneumatic communication with the exterior surface of the chamber body. The second blower is supported below the chamber body and in pneumatic communication with the exterior surface the chamber body. The controller is operatively connected to the first blower and the second blower and is disposed in communication with the first chamber pyrometer and the second chamber pyrometer. The controller is responsive to recorded on a memory to receive the first temperature measurement from the first chamber pyrometer, receive the second temperature measurement from the second chamber pyrometer, determine a longitudinal wall temperature difference using the first temperature measurement and the second temperature measurement, and throttle mass flow rate of coolant through one of the first blower and the second blower relative to mass flow rate of coolant through the other of the first blower and the second blower when a wall exterior surface temperature difference is greater than the predetermined wall temperature difference value.

A material layer deposition method is provided. The method includes, at a chamber arrangement for a semiconductor processing system as described above, acquiring a first temperature measurement at a first location on the exterior surface of the chamber body and acquiring a second temperature measurement at a second location on the exterior surface of the chamber body. The second location is offset from the first location on the exterior surface of the chamber body. Determining a wall temperature difference using the first temperature measurement and the second temperature measurement. Throttling at least one of heating of the chamber body and mass flow rate of coolant through one of a first blower and a second blower relative to mass flow rate of coolant through the other of the first blower and the second blower when the wall temperature difference is greater than a predetermined wall temperature difference value.

In addition to one or more of the features described above, or as an alternative, further examples of the method may include where the wall temperature difference is at least one of a longitudinal wall temperature difference and a lateral wall temperature difference.

In addition to one or more of the features described above, or as an alternative, further examples of the method may include where throttling heating of the chamber body comprises at least one of changing power applied to one of a first lower heater element and a second lower heater element relative to the other of the first lower heater element and the second lower heater element, changing power applied to one of a first lower heater element and a second lower heater element relative to the other of the first lower heater element and the second lower heater element, and changing power applied to one of a first lower spot lamp and a second lower spot lamp relative to the other of the first lower spot lamp and the second lower spot lamp.

In addition to one or more of the features described above, or as an alternative, further examples of the method may include seating a substrate on the substrate support. Heating the substrate to a predetermined material layer deposition temperature using an upper heater element array supported about the chamber body and a lower heater element array supported below the chamber body. Flowing a silicon-containing material layer precursor through the chamber body and across the substrate. Depositing a material layer onto the substrate using the silicon-containing material layer precursor, whereby the temperature of the substrate remains at the predetermined material layer deposition temperature during the throttling heating of the chamber body and heating of the substrate support when a longitudinal wall temperature difference is greater than a predetermined wall temperature difference value.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic diagram of a semiconductor processing system in accordance with the present disclosure, showing a chamber arrangement with a chamber body that may exhibit wall temperature differences during deposition of a material layer onto substrates;

FIG. 2 is a cross-sectional side view of the chamber arrangement of FIG. 1 according to an example of the present disclosure, showing chamber pyrometers to acquire wall temperatures of the chamber body to control wall temperature difference of the chamber body;

FIGS. 3 and 4 are top plan and bottom plan views of the chamber arrangement of FIG. 1 according to an example of the present disclosure, showing heater elements that may be independently throttled to control wall temperature difference of the chamber body;

FIG. 5 is a side view of the chamber arrangement of FIG. 1 according to an example of the present disclosure, showing a first blower and a second blower that may be independently throttled to control wall temperature difference of the chamber body; and

FIGS. 6-8 are a block diagram of a material layer deposition method according to the present disclosure, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

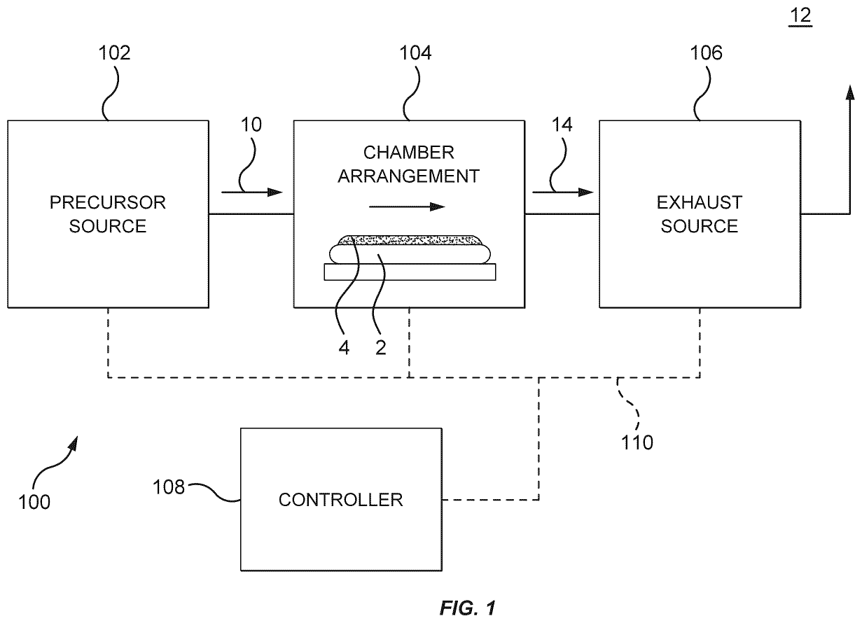

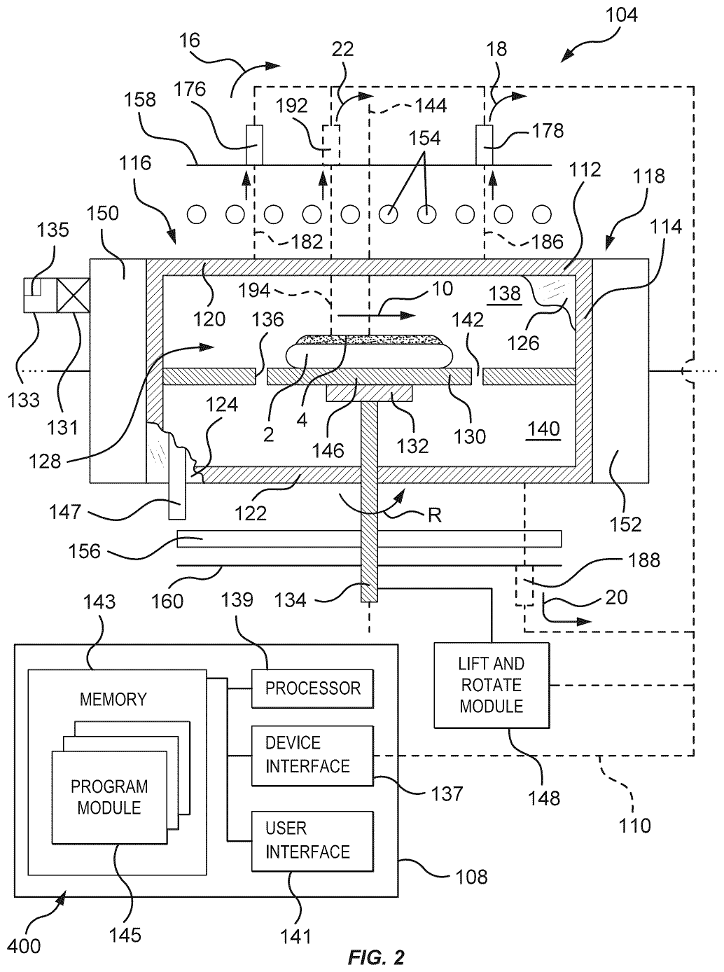

Reference will now be made to the drawings wherein like reference numerals identify similar structural features or aspects of the subject disclosure. For purposes of explanation and illustration, and not limitation, a partial view of an example of a semiconductor processing system having a chamber arrangement in accordance with the present disclosure is shown in FIG. 1 and is designated generally by reference character 100. Other examples of semiconductor processing systems, chamber arrangements and material layer deposition methods in accordance with the present disclosure or aspects thereof, are provided in FIGS. 2-8, as will be described. The systems and methods of the present disclosure may be used to control the temperature variation within the bulk material forming chamber bodies in semiconductor processing systems, such as by limiting wall temperature difference in the general direction of material layer precursor flow in single-substrate quartz chambers having crossflow architectures used to deposit silicon-containing material layers using epitaxial deposition techniques, though present disclosure is not limited to any particular chamber architecture or material layer deposition technique in general.

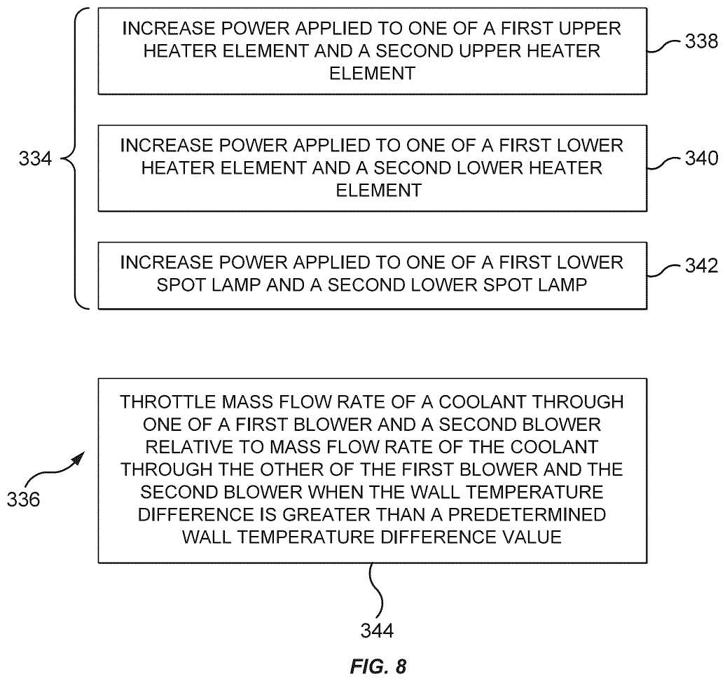

Referring to FIG. 1, the semiconductor processing system 100 is shown. The semiconductor processing system 100 generally includes a precursor source 102, a chamber arrangement 104, an exhaust source 106, and a controller 108. The precursor source 102 is connected to the chamber arrangement 104 and is configured to provide a flow of a material layer precursor 10 to the chamber arrangement 104. The chamber arrangement 104 is connected to the exhaust source 106 and is configured to flow a material layer precursor 10 across a substrate 2 seated within the chamber arrangement 104 under environmental conditions selected to cause a material layer 4 to deposit onto the substrate 2. The exhaust source 106 is in fluid communication with an external environment 12 outside of the semiconductor processing system 100 and is configured to communicate a flow of residual material precursor and/or reaction products 14 to the external environment 12 outside of the semiconductor processing system 100. The controller 108 is operatively connected to the semiconductor processing system 100, for example through a wired or wireless link 110, (e.g., to one or more of the precursor source 102, the chamber arrangement 104, and exhaust source 106) and is configured to deposit the material layer 4 onto the substrate 2 according to operations of a method 300 (shown in FIG. 8), as will be described. In certain examples exhaust source 106 may include one or more of a vacuum pump and an abatement device like a scrubber.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates may be made from semiconductor materials, including, for example, silicon (Si), silicon germanium (SiGe), silicon oxide (SiO₂), gallium arsenide (GaAs), gallium nitride (GaN) and silicon carbide (SiC). As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

With reference to FIGS. 2-5, the chamber arrangement 104 and the controller 108 are shown according to examples of the present disclosure. As shown in FIG. 2, the chamber arrangement 104 may have a single-substrate crossflow architecture and include a chamber body 112. The chamber body 112 may be formed at least partially from a transparent material 114, e.g., a material transparent to electromagnetic radiation in an infrared waveband and extend longitudinally between an injection end 116 and an exhaust end 118. The chamber body 112 may further have an upper wall 120, a lower wall 122, a first sidewall 124, and a second sidewall 126. The upper wall 120 may extend longitudinally between the injection end 116 and the exhaust end 118 of the chamber body 112, be formed from the transparent material 114, and be substantially planar in shape. The lower wall 122 may be similar to the upper wall 120 of the chamber body 112 and additionally be spaced apart from the upper wall 120 by an interior 128 (e.g., a hollow interior) of the chamber body 112. The first sidewall 124 and second sidewall 126 may in turn be laterally spaced apart from one another by the interior 128 of the chamber body 112 and further couple the upper wall 120 of the chamber body 112 to the lower wall 122 of the chamber body 112. In certain examples, the first sidewall 124 and/or the second sidewall 126 may be substantially orthogonal relative to the upper wall 120 and/or the lower wall 122 of the chamber body 112. In accordance with certain examples, the chamber body 112 may include a plurality of external ribs 147 extending laterally about exterior surfaces of the chamber body 112 and laterally spaced apart from one another between the injection end 116 and the exhaust end 118 of the chamber body 112. It is also contemplated that the chamber body 112 may be formed from a ceramic material, such as quartz or sapphire by way of non-limiting examples.

The chamber arrangement 104 may also include a substrate support 130, a support member 132, a shaft member 134, and a divider 136. The divider 136 may be fixed within the interior 128 of the chamber body 112, divide the interior 128 of the chamber body 112 into an upper chamber 138 and a lower chamber 140, and define a divider aperture 142 therethrough fluidly coupling the lower chamber 140 of the chamber body 112 to the upper chamber 138 of the chamber body 112. The substrate support 130 may be configured to support the substrate 2 during deposition of the material layer 4 onto the substrate 2 and in this respect may be arranged within the interior 128 of the chamber body 112. In further respect, the substrate support 130 may be at least partially in the divider aperture 142 and supported therein for rotation R about a rotation axis 144 and may be formed from an opaque material 146 (e.g., a material opaque to electromagnetic radiation within an infrared waveband). The support member 132 may be arranged within the lower chamber 140 of the chamber body 112 and along the rotation axis 144, may also be formed from the transparent material 114, and may be fixed in rotation relative to the substrate support 130. The shaft member 134 may extend from the support member 132 along the rotation axis 144 and through the lower wall 122 of the chamber body 112 and may be fixed in rotation relative to the support member 132. It is contemplated that the shaft member 134 may be formed from the transparent material 114, and that the shaft member 134 operably connect a lift and rotate module 148 to the substrate support 130. In certain examples, the opaque material 146 may include a carbonaceous material, such as graphite or pyrolytic carbon. In accordance with certain examples, the opaque material 146 may include a ceramic material, such as silicon carbide, and/or both a carbonaceous material like graphite and a ceramic material such as silicon carbide.

The chamber arrangement 104 may further include an injection flange 150, an exhaust flange 152, an upper heater element array 154, and a lower heater element array 156. The injection flange 150 may abut the injection end 116 of the chamber body 112 and may couple to the precursor source 102 (shown in FIG. 1) to the chamber body 112 to provide the flow of the material layer precursor 10 to the chamber body 112. The exhaust flange 152 may abut the exhaust end 118 of the chamber body 112, couple the chamber body 112 to the exhaust source 106 (shown in FIG. 1), and be configured to communicate the flow or residual precursor and/or reaction products 14 (shown in FIG. 1) issued by the chamber arrangement 104 to the exhaust source 106. It is further contemplated that the injection flange 150 may couple a gate valve 131 to the chamber body 112 to provide access to the interior 128 of the chamber body 112 to a substrate transfer robot 133 supported outside of the chamber body 112. The substrate transfer robot 133 may in turn be configured to load and unload the substrate 2 from the interior 128 of the chamber body 112, for example using an end effector 135. The end effector 135 may be configured to cooperate with the lift and rotate module 148 to seat the substrate 2 on the substrate support 130 prior to deposition of the material layer 4 onto the substrate 2 and unseat the substrate 2 from the substrate support 130 subsequent to deposition of the material layer 4 onto the substrate 2.

The upper heater element array 154 may be configured to communicate heat into the interior 128 of the chamber body 112 (e.g., radiantly using infrared radiation in an infrared waveband) and in this respect is optically coupled to the interior 128 of the chamber body 112 by the upper wall 120 of the chamber body 112. The upper heater element array 154 may further be separate an upper reflector 158 from the chamber body 112 and operably associated with the controller 108. In this respect the controller 108 may be configured to throttle (e.g., change by increasing or decreasing) heat generated by upper heater elements of the upper heater element array 154 and communicated into the interior 128 of the chamber arrangement 104, for example using silicon-controlled rectifiers coupling the upper heater elements of the upper heater element array 154 to a power source. The lower heater element array 156 may be similar to the upper heater element array 154, additionally be supported below the lower wall 122 of the chamber body 112 and separate a lower reflector 160 from the chamber body 112. In certain examples the silicon-controlled rectifiers and power source operatively associated with upper heater element array 154 and/or the lower heater element array 156 may be as shown and described in U.S. patent application Ser. No. 18/458,101 to Lu et al., filed on Aug. 29, 2023, the contents of which are incorporated herein by reference in their entirety.

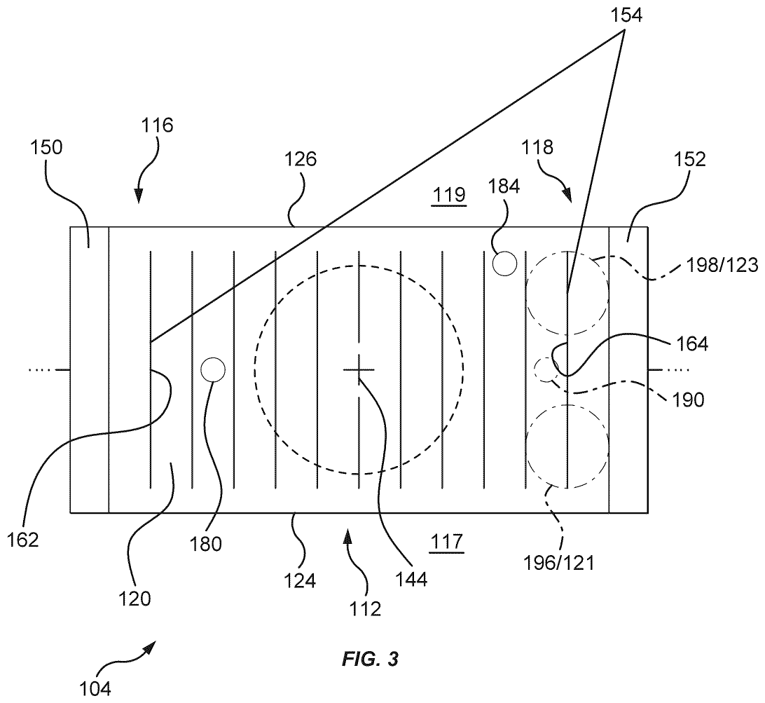

As shown in FIG. 3, the upper heater element array 154 is shown according to an example of the present disclosure. The upper heater element array 154 may include a first upper heater element 162 and one or more second upper heater element 164. The first upper heater element 162 and the one or more second upper heater element 164 may be supported above the upper wall 120 of the chamber body 112 and may extend laterally between the first sidewall 124 and the second sidewall 126 of the chamber body 112. The first upper heater element 162 and the one or more second upper heater element 164 may further be longitudinally spaced apart from one another between the injection end 116 and the exhaust end 118 of the chamber body 112 and may be substantially parallel to one another. It is contemplated that the first upper heater element 162 may be proximate the injection end 116 of the chamber body 112 and in this respect may be located longitudinally between the rotation axis 144 and the injection end 116 of the chamber body 112. The one or more second upper heater element 164 may be proximate the exhaust end 118 of the chamber body 112, for example, at a location longitudinally between the rotation axis 144 and the exhaust flange 152. In certain examples, the first upper heater element 162 and/or the one or more second upper heater element 164 may include a linear lamp, such as linear lamp including a linear filament housed within a quartz tube.

It is contemplated that the controller 108 (shown in FIG. 1) may be configured to throttle (e.g., change by increasing or decreasing) heat communicated one of the first upper heater element 162 and the one or more second upper heater element 164 relative to the other of the first upper heater element 162 and the one or more second upper heater element 164. Throttling may accomplished by throttling (e.g., changing by increasing or decreasing) power applied to the first upper heater element 162 and the one or more second upper heater element 164 relative to the other of the first upper heater element 162. In this respect the controller 108 may be configured to individually throttle power applied to either (or both) the first upper heater element 162 and the one or more second upper heater element 164, for example using silicon-controlled rectifiers individually coupling the first upper heater element 162 and the one or more second upper heater element 164 to a power source. As will be appreciated by those of skill in the art in view of the present disclosure, individually throttling heat generated by upper heater elements of the upper heater element array 154 may change a wall temperature difference along the exterior surface of the upper wall 120 of the chamber body 112. As shown and described herein the upper heater element array 154 includes eleven (11) upper heater elements. As will be appreciated by those of skill in the art in view of the present disclosure, the upper heater element array 154 may include fewer or additional upper heater elements that shown and described herein, and/or include another type of heater element such as bulb-type heater elements in other examples, and remain within the scope of the present disclosure.

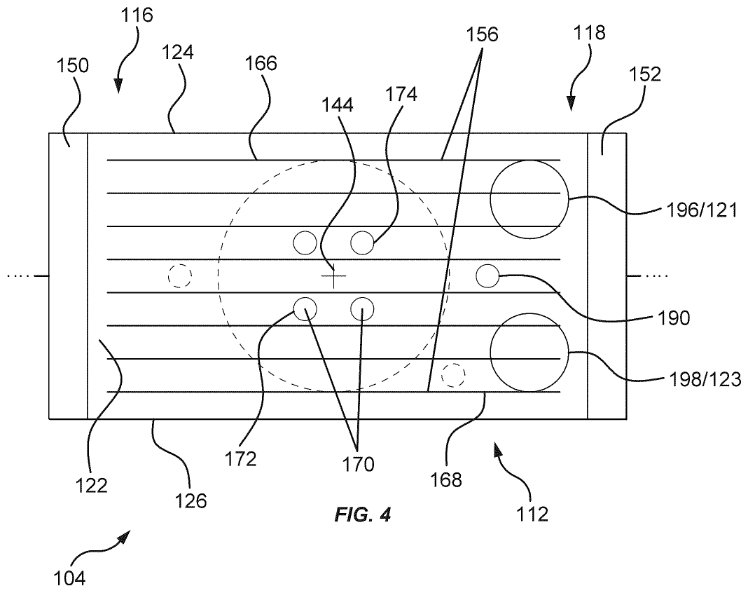

As shown in FIG. 4, the lower heater element array 156 is shown according to an example of the present disclosure. The lower heater element array 156 may be similar to the upper heater element array 154 (shown in FIG. 2) and this respect may include a first lower heater element 166 and one or more second lower heater element 168. The first lower heater element 166 and the one or more second lower heater element 168 may be supported below the lower wall 122 of the chamber body 112 and extend longitudinally between the injection end 116 and the exhaust end 118 of the chamber body 112. The first lower heater element 166 and the one or more second lower heater element 168 may further be laterally spaced apart from one another below the chamber body 112, the one or more second lower heater element 168 being substantially parallel to the first lower heater element 166 in certain examples of the present disclosure. It is contemplated that the first lower heater element 166 may be proximate the first sidewall 124 of the chamber body 112 and in this respect may be located laterally between the rotation axis 144 and the first sidewall 124. The one or more second lower heater element 168 may be proximate the second sidewall 126 of the chamber body 112, for example, at a location laterally between the rotation axis 144 and the second sidewall 126 of the chamber body 112. In certain examples, the first lower heater element 166 and/or the one or more second lower heater element 168 may include a linear lamp, such as linear lamp including a linear filament housed within a quartz tube.

In accordance with certain examples, the controller 108 (shown in FIG. 1) may be configured to throttle (e.g., change by increasing or decreasing) heat communicated by one of the first upper heater element 162 and the one or more second upper heater element 164 relative to the other of the first upper heater element 162 and the one or more second lower heater element 168. Throttling may accomplished by throttling (e.g., changing by increasing or decreasing) power applied to the first lower heater element 166 and the one or more second lower heater element 168 relative to the other of the first lower heater element 166. In this respect the controller 108 may be configured to individually throttle power applied to either (or both) the first lower heater element 166 and the one or more second lower heater element 168 for example using silicon-controlled rectifiers individually coupling the first lower heater element 166 and the one or more second lower heater element 168 to a power source. As shown and described herein the lower heater element array 156 includes twelve (12) lower heater elements. As will be appreciated by those of skill in the art in view of the present disclosure, individually throttling heat generated by lower heater elements of the lower heater element array 156 may compensate for substrate temperature change potentially associated with upper heater element heat output changes, enabling control of the wall temperature difference along the exterior surface of the upper wall 120 of the chamber body 112 without influencing temperature of the substrate 2 (shown in FIG. 1). As will be appreciated by those of skill in the art in view of the present disclosure, the lower heater element array 156 may include fewer or additional upper heater elements, and/or include bulb-type heater elements, in other examples and remain within the scope of the present disclosure.

In certain examples of the present disclosure the chamber arrangement 104 may include a lower spot lamp array 170. The lower spot lamp array 170 may include a plurality of lower spot lamps, e.g., a first lower spot lamp 172 and one or more second lower spot lamp 174, supported below the chamber body 112 and circumferentially distributed about the rotation axis 144. The plurality of lower spot lamps may be optically coupled to the interior 128 (shown in FIG. 2) of the chamber body 112 by the lower wall 122 of the chamber body 112 and configured to radiantly heat the substrate 2 (shown in FIG. 1), for example infrared radiation within an infrared waveband communicated into the interior 128 of the chamber body 112. It is contemplated that the plurality of lower spot lamps may be operably associated with the controller 108 (shown in FIG. 1), and that controller 108 in turn may be configured to throttle (e.g., change by increasing or decreasing) heat communicated by one or more of the plurality of lower spot lamps relative to another of the plurality of lower spot lamps. In this respect it is contemplated that the controller 108 may be configured to throttle power provided by one of the first lower spot lamp 172 and the one or more second lower spot lamp 174 relative to the other of the first lower spot lamp 172 and the one or more second lower spot lamp 174. Throttling may be accomplished, for example, using silicon-controlled rectifiers individually coupling the first lower spot lamp 172 and the one or more second lower spot lamp 174 to power source. As will be appreciated by those of skill in the art in view of the present disclosure, individually throttling heat generated by lower spot lamps of the lower spot lamp array 170 may also compensate for heat output changes made to the upper heater element array 154 (shown in FIG. 2), also limiting (or eliminating) substrate temperature change otherwise potentially associated with heat output change made to the upper heater element array 154 to control wall temperature differences. In the illustrated example the lower spot lamp array 170 includes four (4) lower spot lamps. As will be appreciated by those of skill in art in view of the present disclosure, the lower spot lamp array 170 may include fewer or additional lower spot lamps and remain within the scope of the present disclosure.

With continuing reference to FIG. 2, it is contemplated that the chamber arrangement 104 include a first chamber pyrometer 176 and a second chamber pyrometer 178. The first chamber pyrometer 176 is configured to acquire a first temperature measurement 16 indicative of temperature of the upper wall 120 of the chamber body 112 at a first location 180 (shown in FIG. 3) on an exterior surface of the upper wall 120 of the chamber body 112. In this respect it is contemplated that the first chamber pyrometer 176 be optically coupled to the upper wall 120 of the chamber body 112 at the first location 180 by a first chamber pyrometer optical axis 182 and configured to acquire the first temperature measurement 16 using electromagnetic radiation emitted by the transparent material 114 forming the upper wall 120 of the chamber body 112 at the first location 180. It is further contemplated that the first chamber pyrometer 176 be disposed in communication with the controller 108, for example via the wired or wireless link 110, to provide the first temperature measurement 16 to the controller 108. In certain examples the first location 180 may be longitudinally between the rotation axis 144 and the injection end 116 of the chamber body 112. In accordance with certain examples, the first location 180 may overlay the divider 136. It is also contemplated that the first location 180 may overlay the substrate support 130 and remain within the scope of the present disclosure. As will be appreciated by those of skill in the art, temperature measurements acquired using the first chamber pyrometer 176 enable real time temperature monitoring of wall temperature at the first location 180 on the exterior surface of the upper wall 120 of the chamber body 112.

The second chamber pyrometer 178 may be similar to the first chamber pyrometer 176 and additionally be configured to acquire a second temperature measurement 18 indicative of temperature of the upper wall 120 of the chamber body 112 at a second location 184 (shown in FIG. 3) on the exterior surface of the upper wall 120 of the chamber body 112. It is contemplated that the second chamber pyrometer 178 be optically coupled to the chamber body 112 at the second location 184 by a second chamber pyrometer optical axis 186 and configured to acquire the second temperature measurement 18 using electromagnetic radiation emitted by the transparent material 114 forming the upper wall 120 of the chamber body 112 at the second location 184. It is further contemplated that the second location 184 may be offset from the first location 180 (shown in FIG. 3) on the upper surface of the upper wall 120 of the chamber body 112. For example, the second location 184 may be longitudinally offset from the first location 180 along the exterior surface of the upper wall 120 of the chamber body 112, the second location 184 being separated from the first location 180 by the rotation axis 144 or the substrate support 130 in certain examples of the present disclosure. In certain examples the second location 184 may be laterally offset from the first location 180 on the exterior surface of the upper wall 120 of the chamber body 112, the second location 184 being proximate one of the first sidewall 124 and the second sidewall 126 of the chamber body 112 and the first location 180 being proximate the other of the first sidewall 124 and the second sidewall 126 of the chamber body 112. In accordance with certain examples of the present disclosure, the second location 184 may be longitudinally between the rotation axis 144 and the exhaust end 118 of the chamber body 112. It is also contemplated that the second location 184 may overlay one of the divider 136 and the substrate support 130 and remain within the scope of the present disclosure.

In certain examples, the chamber arrangement 104 may include a third chamber pyrometer 188. The third chamber pyrometer 188 may be similar to the first chamber pyrometer 176, supported below the chamber body 112, and configured to acquire a third temperature measurement 20 of the chamber body 112 at a third location 190 (shown in FIG. 3) using electromagnetic emitted by the lower wall 122 and received by the lower pyrometer 188. The third location 190 may be located on the lower wall 122 of the chamber body 112 and the third temperature measurement 20 indicative of temperature of the lower wall 122 of the chamber body 112, which may be used for adjusting the mean of the first temperature measurement 16 and the second temperature measurement 18, for example to monitor parasitic film deposition on an interior surface of the upper wall 120 of the chamber body 112 and thereby transmissivity of the transparent material 114 forming the upper wall 120 of the chamber body 112. As will be appreciated by those of skill in the art in view of the present disclosure, monitoring transmissivity of the transparent material 114 can ensure accuracy of temperature measurements acquired using substrate pyrometers for real-time temperature control of the substrate 2 during deposition of the material layer 4 onto the substrate 2. In this respect the chamber arrangement 104 may include one or more substrate pyrometer 192. The one or more substrate pyrometer 192 may be supported above the chamber body 112 and configured to acquire a substrate temperature measurement 22 indictive of temperature of the substrate 2 and/or the material layer 4 using electromagnetic radiation emitted by the substrate 2 and/or the material layer 4 along a substrate pyrometer optical axis 194 extending through the upper wall 120 of the chamber body 112 and intersecting the substrate support 130. In certain examples the one or more substrate pyrometer may be as shown and described in U.S. Patent Application Publication No. 2022/0301905 A1 to Ye et al., filed on Mar. 17, 2022, the contents of which are incorporated herein by reference their entirety.

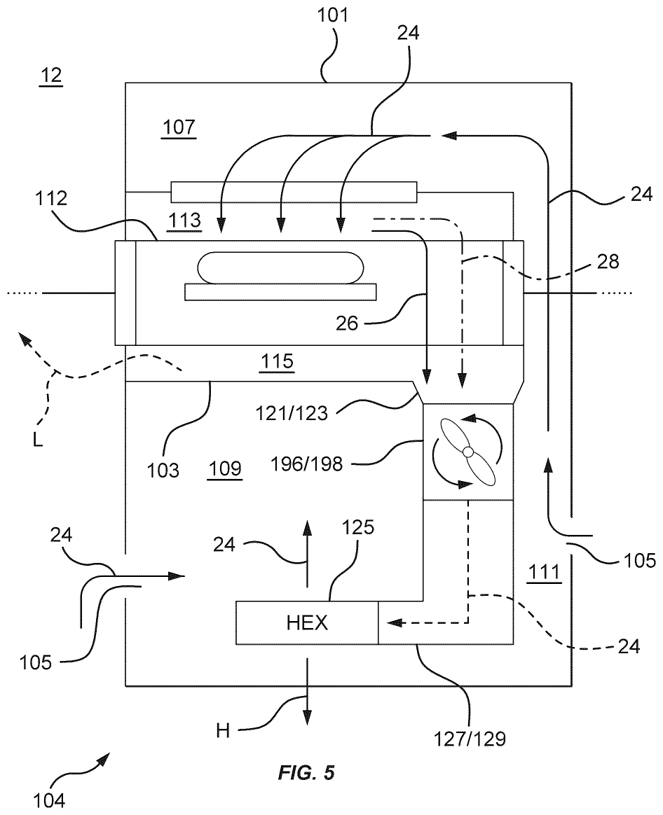

Referring to FIG. 5, it is contemplated the chamber arrangement 104 may have an externally cooled cold-wall chamber architecture. In this respect the chamber arrangement 104 may include a first blower 196 and a second blower 198. The first blower 196 may be operably associated with the controller 108 (shown in FIG. 1) and configured to circulate a coolant 24 about an exterior of the chamber body 112. In this respect the first blower 196 may be supported below the chamber body 112 and at a location longitudinally between the rotation axis 144 (shown in FIG. 2) and the exhaust end 118 (shown in FIG. 2) of the chamber body 112, the first blower 196 overlapped by the chamber body 112 in such examples. In further respect, the first blower 196 may be configured circulate the coolant 24 pneumatically, such as coolant including ambient air made up the external environment 12 outside of the chamber arrangement 104.

In certain examples, the coolant 24 may be circulated about the exterior surfaces of the chamber body 112 using a downflow regime. In such examples the coolant 24 (cooled coolant 24 shown in solid arrows in FIG. 5) may flow across the upper wall 120 (shown in FIG. 2) of the chamber body 112 and be divided thereon into a first sidewall coolant flow 26 and the a second sidewall coolant flow 28, which in turn thereafter flow downward (relative to gravity) across the first sidewall 124 (shown in FIG. 2) and the second sidewall 126 (shown in FIG. 2) of the chamber body 112, respectively, after removing heat from the upper wall 120 of the chamber body 112. It is contemplated that the first sidewall coolant flow 26 and the second sidewall coolant flow 28 (shown in FIG. 5 with solid and dashed-dotted arrows, respectively) may thereafter be cooled and returned upward for further circulation about the chamber body 112 to remove additional heat from the chamber body 112. As will be appreciated by those of skill in the art in view of the present disclosure, positioning the first blower 196 and/or the second blower 198 below the chamber body 112 may limit size (e.g., footprint) of the chamber arrangement 104, limiting cost of ownership of the semiconductor processing system 100 (shown in FIG. 1). In accordance with certain examples, the second blower 198 may be similar to the first blower 196 and additionally be laterally offset from the first blower 196. Advantageously, lateral offset of the second blower 198 relative to the first blower 196 enables differentially cooling upper surface of the upper wall 120 of the chamber body 112, for example by throttling (e.g., changing by increasing or increasing) mass flow rate of one of the first sidewall coolant flow 26 and the second sidewall coolant flow 28 relative to the other of the first sidewall coolant flow 26 and the second sidewall coolant flow 28 due to associated differential mass flow splitting of the coolant 24 during traverse of the upper surface of the upper wall 120 of the chamber body 112.

In certain examples the chamber arrangement 104 may further include an outer enclosure 101 and an inner enclosure 103. The outer enclosure 101 may define one or more makeup inlet 105 and enclose (e.g., envelope) the inner enclosure 103. The outer enclosure 101 may further bound one or more of an exterior supply plenum 107 defined above the inner enclosure 103, a makeup plenum 109 defined below the inner enclosure 103, and a supply chase 111 fluidly coupling the makeup plenum 109 to the exterior supply plenum 107. The inner enclosure 103 may at least in part enclose the chamber body 112 and bound an interior supply plenum 113 defined above the upper wall 120 of the chamber body 112, an interior return plenum 115 define below the lower wall 122 of the chamber body 112, and a first lateral chase 117 (shown in FIG. 3) and a second lateral chase 119 (shown in FIG. 3) both coupling the interior supply plenum 113 and the interior return plenum 115. It is contemplated that the first blower 196 and the second blower 198 be fluidly coupled to the interior return plenum 115 by a first upper return duct 121 and a second upper return duct 123, that the first blower 196 and the second blower 198 further be coupled to a heat exchanger 125 by a first lower return duct 127 and a second lower return duct 129, and that the heat exchanger 125 be configured to reject heat to the external environment 12 and fluid coupled to the makeup plenum 109 to return the coolant 24 (now cooled) for recirculation about the chamber body 112.

As has been explained above, heating of the substrate 2 may heat the chamber body 112, for example due to transmission efficiency of the transparent material 114 (shown in FIG. 2) forming the chamber body 112. Since temperature of the transparent material 114 can influence reliability of the chamber arrangement 104, for example by promoting parasitic deposition on interior surfaces of the chamber body 112, the chamber body 112 may be cooled by drawing a flow of the coolant 24 across the exterior surfaces of the chamber body 112. In this respect it is contemplated that first blower 196 and the second blower 198 may draw cool the coolant 24 from the makeup plenum 109 through the supply chase 111 to the exterior supply plenum 107. From the exterior supply plenum 107 the coolant 24 flows into the interior supply plenum 113 through slots extending through the upper reflector 158 and across the upper wall 120 of the chamber body 112. As the coolant traverse the upper wall 120 of the chamber body 112 the coolant divides into the first sidewall coolant flow 26 and the second sidewall coolant flow 28 according to fan speeds of the first blower 196 and the second blower 198, the first sidewall coolant flow 26 being ingested by the first blower 196 via the first upper return duct 121 and driven thereby to the heat exchanger 125 through the first lower return duct 127, the second sidewall coolant flow 28 being ingested by the second blower 198 via the second upper return duct 123 and driven thereby to the heat exchanger 125 (heated coolant 24 shown with a dashed arrow in FIG. 5) through the second lower return duct 129. The heat exchanger 125 in turn removes heat from both the first sidewall coolant flow 26 and the second sidewall coolant flow 28, for example using a liquid coolant circuit provided to the chamber arrangement 104 and returns the first sidewall coolant flow 26 and the second sidewall coolant flow 28 once cooled to the makeup plenum 109 for communication to the chamber body 112.

In some chamber arrangements 104, one or more leakage path L may exist through either or both the inner enclosure 103 and the outer enclosure 101, a portion of the coolant thereby leaking from within either (or both) the inner enclosure 103 and the outer enclosure 101. Since such leakage may alter distribution of the coolant 24 traversing the upper wall 120 (shown in FIG. 2) of the chamber body 112 it is contemplated that the controller 108 (shown in FIG. 1) be configured to throttle (e.g., change by increasing or decreasing) mass flow of the coolant 24 flowing through one of the first blower 196 and the second blower 198 relative to the other of the first blower 196 and the second blower 198. Throttling flow rate of the coolant 24 through one of the first blower 196 and the second blower 198 relative to the other of the first blower 196 and the second blower 198 in turn throttles (e.g., changes by increasing or decreasing) mass flow rate of one of the first sidewall coolant flow 26 and the second sidewall coolant flow 28 relative to the other of the first sidewall coolant flow 26 and the second sidewall coolant flow 28. Throttling mass flow rate of one of the first sidewall coolant flow 26 and the second sidewall coolant flow 28 relative to the other of the first sidewall coolant flow 26 and the second sidewall coolant flow 28 in turn changes distribution of the coolant 24 traversing the upper surface of the upper wall 120 (shown in FIG. 2) of the chamber body 112. As will be appreciated by those of skill in the art, changing distribution of coolant flow across the upper surface of the upper wall 120 of the chamber body 112 differentially cools the upper wall 120 of the chamber body 112, enables throttling of blower speeds to be employed to control of wall temperature difference that may exist within the transparent material 114 (shown in FIG. 2) forming the chamber body 112 (e.g., lateral wall temperature differences), limiting or eliminating the effect that such wall temperature differences that may otherwise have on properties of the material layer 4 being deposited onto the substrate 2.

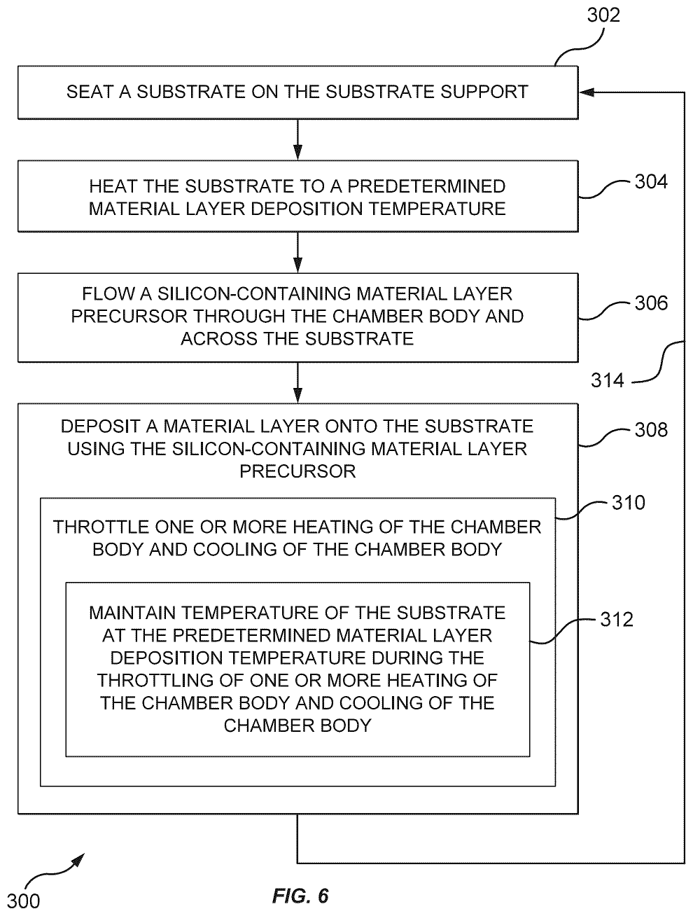

Referring once again to FIG. 2, the controller 108 may include a device interface 137, a processor 139, a user interface 141 and a memory 143. The device interface 137 may couple the processor 139 to the wired or wireless link 110 and therethrough to the one or more of the aforementioned devices of the semiconductor processing system 100 (shown in FIG. 1). The processor 139 may be operably connected to the user interface 141, for example to receive user input from user through the user interface 141 and/or provide user output to the user through the user interface 141 and is disposed in communication with the memory 143. The memory 143 may include a non-transitory machine-readable medium having a plurality of program modules 145 recorded thereon that, when read by the processor 139, cause the processor 139 to execute certain operations. Among the operations are operations of a material layer deposition method 300 (shown in FIG. 6), as will be described, and in respect the non-transitory machine-readable medium may be included in a computer program product 400 containing instructions in program modules to execute the material layer deposition method 300. Although shown and described herein as having a specific architecture it is to be understood and appreciated that the controller 108 may have a different architecture in other examples of the present disclosure, e.g., a distributed computing architecture, and remain within the scope of the present disclosure.

As will be appreciated by those of skill in the art in view of the present disclosure, conditions may develop within the outer enclosure 101 and/or the inner enclosure 103 such that the temperature of the transparent material 114 forming the chamber body 112 has a wall temperature difference (e.g., is non-uniform). As the temperature of the transparent material 114 of the chamber body 112 may influence temperature of the material layer precursor 10 within the interior 128 of the chamber body 112, and material layer precursor temperature may in turn influence properties of the material layer 4 deposited onto the substrate 2, wall temperature difference may require monitoring and/or active control in some deposition processes. For examples, in some deposition processes, inconsistent temperatures may lead to material layer precursor 10 accumulation on the interior 128 of the chamber body 112 proximal to the injection end 116 of the chamber body 112 and/or or cross-substrate variation in material layer properties such as thickness and/or resistivity as well as cross-substrate selectivity. Therefore, establishing a desired wall temperature difference (e.g., uniformity or a predetermined wall temperature difference) within the transparent material 114 forming the chamber body 112 prior to flowing the material layer precursor 10 through the chamber body 112 may be advantageous.

The use of the pyrometers may be used to determine inconsistent temperatures of the transparent material 114 of the chamber body 112. Prior to depositing the material layer 4 onto the substrate 2, a longitudinal wall temperature difference may be acquired by using the acquired first temperature measurement 16 acquired by the first chamber pyrometer 176 and the second temperature measurement 18 acquired by the second chamber pyrometer 178. For longitudinal wall temperature differences that are greater than a predetermined value a user may throttle the heating applied to the chamber body 112. Throttling the heating applied to the chamber body 112 may be accomplished by varying the power applied to a first linear lamp, relative to a second linear lamp, of the upper heater element array 154 and/or the lower heater element array 156. However, this throttling may affect the temperature of the substrate 2 and substrate support 130, as determined by the substrate temperature measurement 22 acquired by the substrate pyrometer 192, as the substrate 2 and substrate support 130 rotate R about the rotation axis 144 and the material layer precursor 10 flows through the interior 128 of the chamber body 112 between the injection flange 150 and the exhaust flange 152. As temperature control of the substrate 2 (e.g., cross-substrate temperature uniformity), like wall temperature difference, may also influence properties of the material layer 4 deposited onto the substrate 2, determining a lateral temperature offset using the longitudinal wall temperature difference by varying the power applied to the individual lamps of the heating element arrays may be necessary. As shown in FIG. 2, the upper heater element array 154 may be orthogonal to the lower heater element array 156. The individual linear lamps of the upper heater element array 154 and the lower heater element array 156 are parallel to the adjacent lamp. When the power applied to one or more of the filament-type linear lamps of the upper heater element array 154 is varied an equal and opposite amount of power is applied to one or more of the filament-type linear lamps of the lower heater element array 156. The net result is that the total power applied to the chamber body 112 remains constant. For an isothermal, or near isothermal, transparent material 114 of the chamber body 112, throttling of the heat applied to the transparent material 114 of the chamber body 112 may include varying the power applied to both the upper heater element array 154, the lower heater element array 156, and the individual lamps thereof.

In addition to varying the power applied to the heating elements, the speed of the blowers may also be varied, for example to achieve an isothermal state (e.g., substantially no longitudinal wall temperature difference and/or substantially no lateral wall temperature difference) across the interior surface of the upper wall 120 of the chamber body 112. When the chamber body 112 wall exterior surface temperature difference is greater than a predetermined wall exterior surface temperature value, the controller 108 may instruct the second blower 198 to vary the mass flow rate through the second blower 198 relative to the first blower 196 by varying the speed at which the second blower 198 or the first blower 196 rotates. Stated another way, throttling the mass flow rate of air through one of the first blower 196 and the second blower 198 relative to the mass flow rate of air through the other of the first blower 196 and the second blower 198 may also be performed. By varying the mass air flow through the first blower 196 relative to the second blower 198, the amount of warm mass air being pulled away from the exterior surface of the chamber body 112 will further provide tunable throttling of the heat applied to the chamber body 112. Furthermore, the blower activity may work in tandem with either (or both) the upper heater element array 154 and the lower heater element array 156. As an illustrative and non-limiting example, the power applied to the upper heater element array 154 may be decreased and power applied to the lower heater element array 156 increased, and mass flow rate of the coolant 24 through the first blower 196 may be increased relative to mass flow rate of the coolant 24 through the second blower 198. Other combinations of increasing or decreasing the upper heater element array 154, the lower heater element array 156, the first blower 196, and the second blower 198 exist and are within the scope of the present disclosure.

With reference to FIGS. 6-8, the material layer deposition method 300 is shown according to an illustrative and non-limiting example of the method. As shown in FIG. 6, the method 300 includes seating a substrate on a substrate support, e.g., the substrate 2 (shown in FIG. 1) on the substrate support 130 (shown in FIG. 2), as shown in box 302. The method 300 also includes heating the substrate to a predetermined material layer deposition temperature and flowing a silicon-containing material layer precursor through the chamber body and across the substrate, e.g., the material layer precursor 10 (shown in FIG. 1), as shown with box 304 and box 306. The method 300 further includes depositing a material layer onto the substrate using the silicon-containing material layer precursor, e.g., the material layer 4 (shown in FIG. 1), as shown with box 308. It is contemplated that the method 300 include throttling one or more of heating of a chamber body within the substrate is seated during deposition of the material layer onto the substrate, e.g., the chamber body 112 (shown in FIG. 2) and cooling of the chamber body during deposition of the material layer on the substrate according to a wall temperature difference within the transparent material forming the chamber body, e.g., the transparent material 114, as shown with box 310. It also contemplated that the method 300 may include maintaining temperature of the substrate at the predetermined material layer deposition temperature during throttling or one or more of heating of the chamber body and cooling of the chamber body, as shown with box 310. It is further contemplated that the deposition may be accomplished singularly, i.e., by depositing the material layer on a single substrate and thereafter seating another substrate within the chamber body for deposition, as shown with arrow 314.

Seating 302 the substrate within the chamber body may include opening a gate valve connected to a chamber body, e.g., the gate valve 131 (shown in FIG. 2) connected to the chamber body 112 (shown in FIG. 2), as also shown with box 302. Seating 302 the substrate within the chamber body may also include advancing an end effector into the chamber body using a substrate transfer robot, e.g., the substrate transfer robot 133 (shown in FIG. 2) using the end effector 135 (shown in FIG. 2), as further shown with box 302. Seating 302 the substrate within the chamber body may additionally include transferring the substrate to the substrate support and thereafter withdrawing the end effector from the chamber body and closing the gate valve, as additionally shown with box 302. In certain examples the seating 302 the substrate may include seating one and only one substrate within the chamber body, such as in a single-substrate chamber body, as shown with arrow 314.

Heating 304 the substrate to the predetermined material layer deposition temperature may include radiantly communicating heat into the interior of the chamber body. In certain examples, the substrate may be heated to the predetermined material layer deposition temperature using radiant heat communicated by a plurality of upper heater elements supported above the chamber body, e.g., the plurality of upper heater elements of the upper heater element array 154 (shown in FIG. 2), as also shown with box 304. In accordance with certain examples, the substrate may be heated to the predetermined material layer deposition temperature using radiant heat communicated by a plurality of lower heater elements supported below the chamber body, e.g., the plurality of lower heater elements of the lower heater element array 156 (shown in FIG. 2), as further shown with box 304. It is contemplated that, in certain examples, the substrate may be heated to the predetermined material layer deposition temperature using radiant heat communicated by a plurality of spot lamps supported below the chamber body, e.g., spot lamps of the lower spot lamp array 170 (shown in FIG. 4), as additionally shown with box 304. It is also contemplated that the substrate may be heated to predetermined material layer deposition temperature using two of the plurality of upper linear lamps supported about the chamber, the plurality of lower linear lamps supported below the chamber body, and/or the plurality of spot lamps supported below the chamber body and remain within the scope of the present disclosure, as additionally shown with box 304. Heating may accomplished using a temperature measurement acquired optically from a surface of the substrate and/or a material layer deposited onto the substrate, e.g., using a substrate temperature measurement acquired using the substrate pyrometer 192 (shown in FIG. 2) optically coupled to the substrate along the substrate pyrometer optical axis 194 (shown in FIG. 2), as further shown with box 304.

Flowing 306 the silicon-containing material layer precursor through the chamber body and across the substrate may include introducing the silicon containing precursor into an injection flange abutting the chamber body, e.g., the injection flange 150 (shown in FIG. 2), as also shown with box 306. Flowing 306 the silicon-containing material layer precursor though the chamber body and across the substrate may include flowing the silicon-containing precursor through a chamber body having a cross-flow arrangement and thereafter issuing residual precursor and/or reaction products through an exhaust flange abutting the chamber body to an exhaust source, e.g., through the exhaust flange 152 (shown in FIG. 2) to the exhaust source 106 (shown in FIG. 1), as further shown with box 306. It is contemplated that silicon-containing material layer precursor may include a chlorinated silicon-containing precursor such as silane (SiH₄) or disilane (Si₂H₆) and/or that the silicon-containing precursor may include a chlorinated silicon-containing material layer precursor, such as dichlorosilane (H₂SiCl₂). It is also contemplated that the silicon-containing material layer precursor may be co-flowed with a diluent/carrier gas such as hydrogen (H₂) gas or nitrogen (N₂) gas as well an etchant such as hydrochloric (HCl) acid and remain within the scope of the present disclosure. It is further contemplated that the silicon-containing material layer precursor may be co-flowed with an alloying constituent, such as germanium-containing material layer precursor like germane (GeH₄), and/or with a dopant-containing material layer precursor, such as an n-type or a p-type dopant-containing material layer precursor.

Depositing 308 the material layer onto the substrate using the silicon-containing material layer precursor may include depositing a silicon-containing material layer onto the substrate, as also shown with box 308. In certain examples of the present disclosure the material may be deposited using an epitaxial material layer technique, the material layer being epitaxial in crystalline structure with the underlying substrate in such examples. In accordance with certain examples, the material layer may include germanium (Ge), the material layer being a silicon germanium (SiGe) material layer. It is also contemplated that the material layer may include a dopant, such as an n-type dopant such as arsenic (As) or phosphorous (P) or a p-type dopant (As) like boron (B). As shown with box 312, it is contemplated that heating of the chamber body may be throttled during deposition of the material layer onto the substrate and/or cooling of the chamber body throttled during deposition of the material layer onto the substrate to limit temperature differential within the bulk material forming the chamber body longitudinally and/or laterally along the chamber body while temperature of the substrate is maintained at the predetermined material layer deposition temperature. Advantageously, throttling the heating and/or cooling of the chamber while maintaining the substrate at the predetermined material layer deposition temperature can limit the affect that wall temperature difference may have on deposition of the material layer onto the substrate, such as variation in precursor decomposition product availability longitudinally within the chamber body and across the substrate surface.

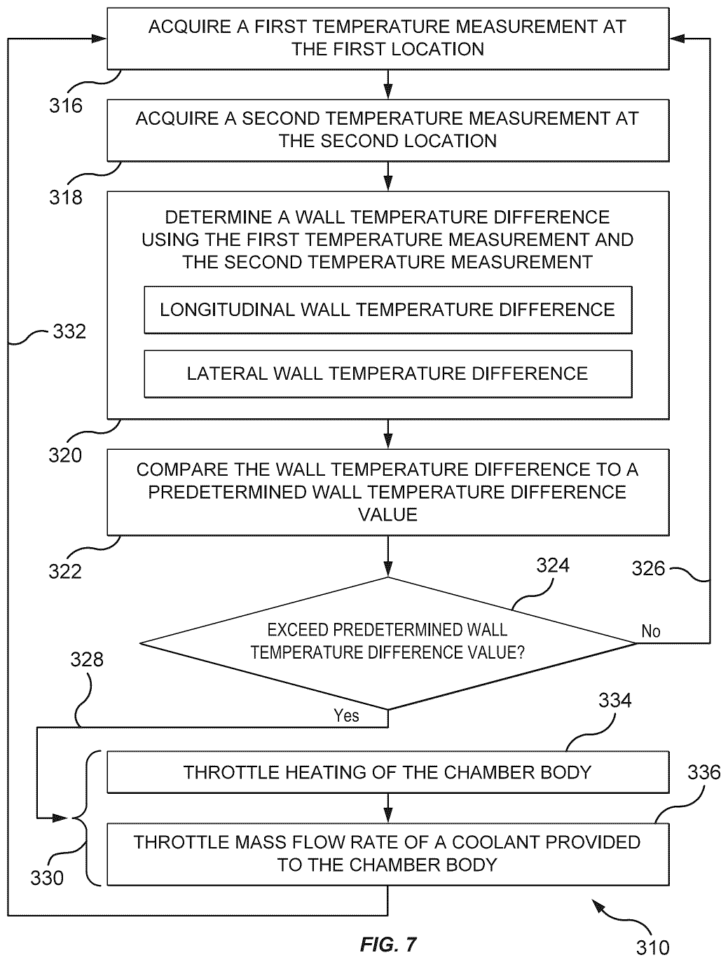

As shown in FIG. 7, throttling 310 heating of the chamber body and/or cooling of the chamber body includes acquiring a first temperature measurement at a first location on the exterior surface of the chamber body, e.g., the first temperature measurement 16 (shown FIG. 2) at the first location 180 (shown in FIG. 3), as shown with box 316. Throttling 310 heating of the chamber body and/or cooling of the chamber body also includes acquiring a second temperature measurement at a second location on the exterior of the chamber body at a second location on the chamber body, e.g., the second temperature measurement 18 (shown in FIG. 2) at the second location 184 (shown in FIG. 3), as shown with box 318. It is contemplated that a wall temperature difference be determined using the first temperature measurement and the second temperature measurement, as shown with box 320, and that the determined wall temperature difference be compared to a predetermined wall temperature difference value, as shown with box 322. When the determined wall temperature difference is less than the predetermined wall temperature difference value no action may be taken, and monitoring may continue, as shown with box 324 and arrow 326. When the determined wall temperature difference is greater than the predetermined wall temperature difference value heating of the chamber body may be throttled and/or flow of a coolant provided to the chamber body may be throttled, as also shown with box 326 and additionally shown with arrow 328 and bracket 330. Once throttling is accomplished monitoring of wall temperature difference in the chamber body may continue, as shown with arrow 332.

Acquiring 316 the first temperature measurement may include acquiring the first temperature measurement optically from an upper surface of an upper wall of the chamber body, e.g., using the first chamber pyrometer 176 (shown in FIG. 2) optically coupled to the upper wall of the chamber body at the first location along the first chamber pyrometer optical axis 182 (shown in FIG. 2), as shown with box 316. Acquiring 318 the second temperature measurement may include acquiring the second temperature measurement optically from the upper surface of the upper wall of the chamber body, e.g., using the second chamber pyrometer 178 (shown in FIG. 2) optically coupled to the upper wall of the chamber body at the second location along the second chamber pyrometer optical axis 186 (shown in FIG. 2), as also shown with box 318. The acquired first temperature measurement and the acquired second temperature measurement may be communicated to a controller, e.g., the controller 108 (shown in FIG. 1) using the wired or wireless link 110 (shown in FIG. 2), as also shown with box 316 and box 318. It is contemplated that the controller may determine the wall temperature difference using the first temperature measurement and the second temperature measurement and compare the wall temperature difference to the predetermined wall temperature difference value, e.g., a predetermined wall temperature difference value recorded on one of a plurality of program modules recorded on a memory of the controller, e.g. a predetermined wall temperature difference value recorded on one of the plurality of program modules 145 (shown in FIG. 2) on the memory 143 (shown in FIG. 2), as also shown with box 320 and box 322, and that the controller may further determine whether throttling of heating or cooling is necessary or unnecessary and thereafter iteratively continue wall temperature difference monitoring, as shown with box 324 and arrows 326 and 332.

In certain examples, the second location on the upper surface of the upper wall of the chamber body whereat the second temperature measurement is acquired may be longitudinally offset from the first location along the upper surface of the upper wall of the chamber body such that the determined wall temperature difference is a longitudinal wall temperature difference, as also shown with box 320. In accordance with certain examples, the second location on the upper surface of the upper wall of the chamber body whereat the second temperature measurement is acquired may be laterally offset from the first location such that the determined wall temperature difference is lateral wall temperature difference, as further shown with box 320. It is also contemplated that, in accordance with certain examples, the second location may be both longitudinally and laterally offset from the first location. In such examples the wall temperature difference value may have both a longitudinal wall temperature difference component and a lateral wall temperature difference component. Advantageously, throttling heating of the chamber body and throttling flow of the coolant provided to the chamber body in such examples may be selected according to the larger of the longitudinal wall temperature difference component and the lateral wall temperature difference, for example by driving greater coolant flow across one lateral side of the chamber body relative to the other lateral side of the chamber body according lateral offset between laterally offset blowers arranged below the chamber body, e.g., the first blower 196 (shown in FIG. 5) and the second blower 198 (shown in FIG. 5), as also shown with box 324, arrow 328, and box 334, and box 336.

As shown in FIG. 8, throttling 334 of the heating of the chamber body may include changing (e.g., increasing or decreasing) power applied to one of a first upper heater element and a second upper heater element lamp relative to the other of the first upper heater element and the second upper heater element, e.g., the first upper heater element 162 (shown in FIG. 3) and the one or more second upper heater element 164 (shown in FIG. 3), as shown with box 338. For example, power applied to an upper heater element proximate the first location may be increased relative to power applied to another upper heater element proximate the second location on the upper surface of the upper wall of the chamber body, as also shown with box 334. As will be appreciated by those or skill in the art in view of the present disclosure, changing power applied to one of the first upper heater element and one or more second upper heater element relative to the other of the first upper heater element and the one or more second upper heater element may reduce the wall temperature difference between the first location and the second location on the upper wall of the chamber body. Reducing the wall temperature difference on the exterior surface may in turn reduce a wall temperature difference on the interior surface of the upper wall of the chamber body. Since the inner surface of the upper wall of the chamber body bounds the material layer precursor flowing through the chamber body and across the substrate, reducing the wall temperature difference limits the effect that the wall temperature difference may have on concentration of available precursor decomposition products across the surface of the substrate, limiting (or eliminating) the effect that such concentration variation may have on properties of the material layer deposited onto the substrate. For example, in selective material layer processes run at relative high pressure (e.g., about 300 torr to about 500 torr) in reduced pressure regimes, limiting wall temperature difference may limit etchant consumption variation otherwise associated with the wall temperature differential, limiting variation in cross-substrate selectivity.

In certain examples of the present disclosure throttling 334 of the heating of the chamber body may include changing (e.g., increasing or decreasing) power applied to one of a first lower heater element and one or more second lower heater element relative to the other of the first lower heater element and the one or more second lower heater element, e.g., the first lower heater element 166 (shown in FIG. 4) and the one or more second lower heater element 168 (shown in FIG. 4), as shown with box 340. For example, power applied to a lower heater element proximate a first sidewall of the chamber body, e.g., the first sidewall 124 (shown in FIG. 2), may be increased relative to power applied to a lower heater element proximate the second sidewall of the chamber body, e.g., the second sidewall 126 (shown in FIG. 2), as also shown with box 340.

As will be appreciated by those or skill in the art in view of the present disclosure, changing power applied to one of the first lower linear lamp and the second lower linear lamp relative to the other of the first lower linear lamp and the second lower linear lamp may reduce (or eliminate) substrate temperature differences potentially driven by power changes made to upper linear lamps to control the aforementioned wall temperature difference that could also otherwise influence properties of the material layer deposited onto the substrate, such as in low pressure material layer deposition processes (e.g., about 5 torr to about 20 torr) in reduced pressure regimes where the deposition rate may be temperature limited.

In certain examples, throttling 334 heating of the chamber body may include changing (e.g., increasing or decreasing) power applied to one of a first lower spot lamp and a second lower spot lamp relative to the other of the first lower spot lamp and the second lower spot, e.g., the first lower spot lamp 172 (shown in FIG. 4) and the one or more second lower spot lamp 174 (shown in FIG. 2), as shown with box 342. The power change may be for the above-described substrate temperature compensation due to wall temperature difference within the upper wall of the chamber body. Alternatively (or additionally) the power chamber may be to cooperate with blower speed changes, as also shown with box 342. It is also contemplated that throttling 332 heating of the chamber body may include two or more of changing power applied to upper linear lamps, lower linear lamps, and lower spot lamps and remain within the scope of the present disclosure, as shown with bracket 338.

Throttling 334 flow of the coolant provided to the chamber body may include changing (e.g., increasing or decreasing) mass flow rate of air through one of a first blower and second blower relative to the other of the first blower and the second blower when the wall temperature difference is greater than the predetermined wall temperature difference, e.g., the first blower 196 (shown in FIG. 3) and the second blower 198 (shown in FIG. 3), as shown with box 344. For example, speed of a first blower proximate the first sidewall of the chamber body, may be changed relative to a second blower proximate the second sidewall of the chamber body, e.g., speed of the first blower relative to speed of the second blower, as also shown with box 344. As will be appreciated by those of skill in the art in view of the present disclosure, changing mass flow rate of air through one of the first blower and the second blower relative to the other of the first blower and the second blower may increase cooling of the upper surface of the chamber body proximate one of the first sidewall and the second sidewall relative to the other of the first sidewall and the second sidewall due to the associated change mass flow of coolant across the sidewalls, limiting (or eliminating) lateral wall temperature differences that may exist on the upper surface of the upper wall of the chamber body. This can also limit (or eliminate) lateral variation in etchant consumption and/or precursor decomposition product concentration in the material layer precursor flowing through the chamber body and across the substrate, limiting variation in material layer properties otherwise potentially associated with the etchant consumption and/or precursor decomposition product concentration.

Semiconductor processing systems, such as semiconductor processing systems employed to deposit silicon-containing material layers onto substrates using epitaxial deposition techniques, may include pyrometers to control temperature during the deposition process. Substrate pyrometers may be optically coupled by the reactor to the substrate to acquire temperature of the substrate during deposition, such as through a transparent window or walls of the rector. Chamber pyrometers may be optically coupled to the reactor walls and employed to monitor temperature of the reactor employed for deposition, such as quartz temperature in cold wall reactors for purposes of controlling temperature of the reactor wall. Typically, reactors employ singular chamber pyrometers to monitor reactor wall temperature during deposition, generally to control average wall temperature for purposes of limiting the accumulation of parasitic deposition on the interior surfaces of the reactor employed for deposition during the deposition process.

While generally satisfactory for its intended purposes, single point measurement of reactor wall temperature may be unable to appreciate wall temperature differences at different locations on the surface of the reactor wall, for example due to variation associated with the setup of the reactor employed for deposition relative to other reactors employed for similar deposition processes. Since rector wall exterior temperature may correspond to interior surface temperature, and precursor flowing through the reactor is in thermal communication with the interior surface of the reactor wall, such wall temperature differences can influence the deposition process within the reactor. For example, a localized region of high temperature on the reactor wall interior surface can locally alter concentration of the precursor decomposition products available for incorporation into the layer being deposited onto the substrate, locally changing the deposition rate on the substrate below the high temperature region and causing variation in properties of the material layer. A localized region of high temperature may also locally change concentration of etchant provided to the substrate for purposes of selectivity, for example in epitaxial processes where the substrate includes both exposed silicon surfaces and exposed dielectric, locally altering the rate at which amorphous or polysilicon is etched from the exposed dielectric surfaces relative to the rate at which epitaxial silicon is deposited onto exposed silicon surfaces and potentially altering properties of devices formed using the material layer.

In examples described herein semiconductor processing systems include chamber arrangements having two or more chamber pyrometers. The chamber pyrometers are optically coupled to the exterior surface of the chamber body at different locations and configured to acquire temperature of the chamber body at different locations. The different chamber body wall temperature measurements are used to determine a wall temperature difference during material layer deposition, and heating of the chamber body and/or cooling of the chamber body is changed according to the wall temperature difference. In certain examples, wall temperature difference may be controlled using an upper heater element array supported above the chamber body, such as in deposition processes where the deposition rate is governed by material layer concentration with the chamber body, such as in mass flow rate limited deposition processes. In accordance with certain examples, wall temperature difference may be controlled using the upper heater element array and a lower heater element array, such as in deposition processes where the deposition rate is temperature limited, the lower heater element array compensating for temperature change the substrate could otherwise be subject due to changes heating of the chamber body by the upper heater element array. It is also contemplated that lower spot lamps of certain chamber arrangements may also be employed to control wall temperature difference, such as also for substrate temperature compensation. In further examples of the present disclosure the temperature measurements acquired using the chamber pyrometers may be employed to locally alter the distribution of coolant provided to the chamber body to control wall temperature difference within the bulk material forming the chamber body during deposition.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A chamber arrangement for a semiconductor processing system, comprising:
a chamber body having an exterior surface and a hollow interior;
a substrate support supported for rotation within the interior of the chamber body;
a first chamber pyrometer optically coupled to the exterior surface of the chamber body at a first location; and
a second chamber pyrometer optically coupled to the exterior surface of the chamber body at a second location, the second location offset from the first location along the exterior surface of the chamber body,
wherein the first chamber pyrometer is configured to acquire a first temperature measurement at the first location and the second chamber pyrometer is configured to acquire a second temperature measurement at the second location on the exterior surface of the chamber body to throttle heat communicated into the interior of the chamber body according to a wall temperature difference between the first location and the second location on the exterior surface of the chamber body calculated using the first temperature measurement and the second temperature measurement.

2. The chamber arrangement of claim 1, wherein the chamber body is formed from a transparent material, wherein the substrate support is formed from an opaque material.

3. The chamber arrangement of claim 1, wherein the chamber body has an injection end and a longitudinally opposite exhaust end, wherein the second location is longitudinally offset from the first location.

4. The chamber arrangement of claim 1, wherein the second location is laterally offset from the first location.

5. The chamber arrangement of claim 1, further comprising a substrate pyrometer optically coupled to the interior of the chamber body by an optical axis intersecting the substrate support.

6. The chamber arrangement of claim 1, further comprising a third chamber pyrometer supported below the chamber body and configured to acquire a temperature measurement of the exterior surface of a lower wall of the chamber body at a third location.

7. The chamber arrangement of claim 1, wherein at least one of the first location and the second location overlays the substrate support.

8. The chamber arrangement of claim 1, wherein the substrate support separates the second location from the first location.

9. A semiconductor processing system, comprising:
a chamber arrangement as recited in claim 1;
an upper heater element array supported above the chamber body and optically coupled to the interior of the chamber body by an upper wall of the chamber body;
a controller operatively connected to the upper heater element array and disposed in communication with both the first chamber pyrometer and the second chamber pyrometer, the controller is responsive to instructions recorded on a memory to:
receive the first temperature measurement from the first chamber pyrometer;
receive the second temperature measurement from the second chamber pyrometer;
determine the wall temperature difference using the first temperature measurement and the second temperature measurement; and
throttle heating of the chamber body when the wall temperature difference is greater than a predetermined wall temperature difference value.

10. The semiconductor processing system of claim 9, wherein the upper heater element array includes a first upper heater element and a second upper heater element extending laterally and in parallel with one another above the chamber body, and wherein heating of the chamber body is throttled by changing power applied to one of the first upper heater element and the second upper heater element relative to the other first upper heater element and the second upper heater element.

11. The semiconductor processing system of claim 9, further comprising a lower heater element array supported below the chamber body and optically coupled to the substrate support by a lower wall of the chamber body, wherein the controller is operably connected to the lower heater element array, and wherein the instructions further cause the controller to:
throttle the heating of the substrate support by the lower heater element array when the wall temperature difference is greater than the predetermined wall temperature difference value.

12. The semiconductor processing system of claim 10, wherein the instructions further cause the controller to determine a lateral temperature offset using the wall temperature difference, wherein heating of the substrate support by a lower heater element array is throttled using the lateral temperature offset.

13. The semiconductor processing system of claim 11, wherein the lower heater element array comprises a first lower heater element and a second lower heater element extending longitudinally below the chamber body, and wherein throttling the lower heater element array using a lateral temperature offset comprises changing power applied to one of the first lower heater element and the second lower heater element relative to the other of the first lower heater element and the second lower heater element.

14. The semiconductor processing system of claim 11, wherein the lower heater element array comprises a first lower spot lamp and a second lower spot lamp underlying the substrate support, wherein throttling the lower heater element array using a lateral temperature offset comprises changing power applied to one of the first lower spot lamp and the second lower spot lamp relative to the other of the first lower spot lamp and the second lower spot lamp.

15. The semiconductor processing system of claim 10, further comprising:
a first blower supported below the chamber body and in pneumatic communication with the exterior surface of the chamber body;
a second blower supported below the chamber body and in pneumatic communication with the exterior surface the chamber body,
wherein the controller is operably connected to the first blower and the second blower, and wherein the instructions further cause the controller to:
throttle mass flow rate of coolant through one of the first blower and the second blower relative to mass flow rate of coolant through the other of the first blower and the second blower when the wall temperature difference is greater than the predetermined wall temperature difference value.

16. A semiconductor processing system, comprising:
a chamber arrangement as recited in claim 1;
a first blower supported below the chamber body and in pneumatic communication with the exterior surface of the chamber body;
a second blower supported below the chamber body and in pneumatic communication with the exterior surface the chamber body;
a controller operatively connected to the first blower and the second blower, wherein the controller is disposed in communication with the first chamber pyrometer and the second chamber pyrometer, and wherein the controller is responsive to recorded on a memory to:
receive the first temperature measurement from the first chamber pyrometer;
receive the second temperature measurement from the second chamber pyrometer;
determine the wall temperature difference using the first temperature measurement and the second temperature measurement; and
throttle mass flow rate of coolant through one of the first blower and the second blower relative to mass flow rate of coolant through the other of the first blower and the second blower when the wall temperature difference is greater than a predetermined wall temperature difference value.

17. A material layer deposition method, comprising:
at a chamber arrangement for a semiconductor processing system including a chamber body having an exterior surface and a hollow interior, a substrate support supported for rotation within the interior of the chamber body, a first chamber pyrometer optically coupled to the exterior surface of the chamber body at a first location on the exterior surface of the chamber body, and a second chamber pyrometer optically coupled to the exterior surface of the chamber body at a second location offset from the first location on the exterior surface of the chamber body,
acquiring a first temperature measurement at the first location on the exterior surface of the chamber body;
acquiring a second temperature measurement at the second location on the exterior surface of the chamber body;
determining a wall temperature difference using the first temperature measurement and the second temperature measurement; and
throttling at least one of (a) heating of the chamber body and (b) mass flow rate of coolant through one of a first blower and a second blower relative to mass flow rate of coolant through the other of the first blower and the second blower when the wall temperature difference is greater than a predetermined wall temperature difference value.

18. The material layer deposition method of claim 17, wherein the wall temperature difference is at least one of (a) a longitudinal wall temperature difference and (b) a lateral wall temperature difference.

19. The material layer deposition method of claim 18, wherein throttling heating of the chamber body comprises at least one of (a) changing power applied to one of a first upper heater element and a second upper heater element relative to the other of the first upper heater element and the second upper heater element, (b) changing power applied to one of a first lower heater element and a second lower heater element relative to the other of the first lower heater element and the second lower heater element, and (c) changing power applied to one of a first lower spot lamp and a second lower spot lamp relative to the other of the first lower spot lamp and the second lower spot lamp.

20. The material layer deposition method of claim 17, further comprising:
seating a substrate on the substrate support;
heating the substrate to a predetermined material layer deposition temperature using an upper heater element array supported about the chamber body and a lower heater element array supported below the chamber body;
flowing a silicon-containing material layer precursor through the chamber body and across the substrate; and
depositing a material layer onto the substrate using the silicon-containing material layer precursor, whereby the temperature of the substrate remains at the predetermined material layer deposition temperature during the throttling heating of the chamber body and heating of the substrate support when the wall temperature difference is greater than the predetermined wall temperature difference value.
